(19) United States
(12) Patent Application Publication
(10) Pub. No.: US 2015/0118836 A1
(43) Pub. Date: Apr. 30, 2015

(54) METHOD OF FABRICATING SEMICONDUCTOR DEVICE

(71) Applicant: United Microelectronics Corp., Hsinchu (TW)

(72) Inventors: Ching-Ling Lin, Kaohsiung City (TW); Chih-Sen Huang, Tainan City (TW); Jia-Rong Wu, Kaohsiung City (TW); Ching-Wen Hung, Tainan City (TW); Po-Chao Tsao, New Taipei City (TW)

(73) Assignee: United Microelectronics Corp., Hsinchu (TW)

(21) Appl. No.: 14/064,722

(22) Filed: Oct. 28, 2013

(51) Int. Cl. H01L 29/66; H01L 21/768

(52) U.S. Cl. CPC H01L 29/66583; H01L 29/66545; H01L 29/6653; H01L 21/76897
USPC 438/586

(57) ABSTRACT

A method of fabricating a semiconductor device is disclosed. Provided is a substrate having a dummy gate formed thereon, a spacer on a sidewall of the dummy gate and a first dielectric layer surrounding the spacer. The dummy gate is removed to form a gate trench. A gate dielectric layer and at least one work function layer is formed in the gate trench. The work function layer and the gate dielectric layer are pulled down, and a portion of the spacer is laterally removed at the same time to widen a top portion of the gate trench. A low-resistivity metal layer is formed in a bottom portion of the gate trench. A hard mask layer is formed in the widened top portion of the gate trench.

### BACKGROUND OF THE INVENTION

1. Field of Invention

The present invention relates to an integrated circuit (IC) fabrication, and particularly to a method of forming a semiconductor device.

2. Description of Related Art

A MOS is a basic structure widely applied to various semiconductor devices, such as memory devices, image sensors and display devices. An electric device is required to be made lighter, thinner and smaller. As the CMOS is continuously minimized, a logic CMOS technology is developed towards a technology having a high dielectric constant (high-k) dielectric layer and a metal gate.

In the conventional metal gate process, the spacer formed beside the metal gate plays an important role in preventing a short from occurring between the metal gate and the adjacent contact plug. However, the hardness of the spacer is decreased after the ion implantation steps, cleaning steps and annealing steps for forming the metal gate. Therefore, the etching selectivity of the spacer is accordingly reduced with respect to the dielectric layer between the metal gates. In such case, a short occurs between the metal gate and the adjacent contact plug, and the device performance is thus deteriorated.

### SUMMARY OF THE INVENTION

The present invention provides a method of forming a semiconductor device, by which a short between the metal gate and the adjacent contact plug is not observed, so that the device performance can be accordingly improved.

The present invention provides a method of forming a semiconductor device. Provided is a substrate having a dummy gate formed thereon, a spacer on a sidewall of the dummy gate and a first dielectric layer surrounding the spacer. The dummy gate is removed to form a gate trench. A gate dielectric layer and at least one work function layer is formed in the gate trench. The work function layer and the gate dielectric layer are pulled down, and a portion of the spacer is laterally removed at the same time to widen a top portion of the gate trench. A low-resistivity metal layer is formed in a bottom portion of the gate trench. A hard mask layer is formed in the widened top portion of the gate trench.

According to an embodiment of the present invention, the method further includes: forming a second dielectric layer covering the hard mask layer and the first dielectric layer, removing a portion of the second dielectric layer and a portion of the first dielectric layer to form a contact opening; and forming a contact plug in the contact opening.

According to an embodiment of the present invention, the hard mask layer and the spacer have different removing rates.

According to an embodiment of the present invention, the substrate is a substrate with fins extending in a first direction, and the dummy gate crosses the fins and extend in a second direction different from the first direction.

According to an embodiment of the present invention, the method further includes forming epitaxial layers on the fins beside the dummy gate after the spacer is formed, wherein the contact plug is electrically connected to one of the epitaxial layers.

According to an embodiment of the present invention, the substrate is a bulk substrate.

According to an embodiment of the present invention, the method further includes forming epitaxial layers in the substrate beside the dummy gate after the spacer is formed, wherein the contact plug is electrically connected to one of the epitaxial layers.

According to an embodiment of the present invention, the step of forming the low-resistivity metal layer includes: forming a low-resistivity metal material layer on the substrate filling the gate trench; removing the low-resistivity metal material layer outside of the gate trench; and removing the low-resistivity metal material layer in the top portion of the gate trench.

According to an embodiment of the present invention, the method further includes laterally removing another portion of the spacer during the step of removing the low-resistivity metal material layer in the top portion of the gate trench, so as to further widen the top portion of the gate trench.

According to an embodiment of the present invention, the step of removing the low-resistivity metal material layer outside of the gate trench includes performing a CMP process.

According to an embodiment of the present invention, the hard mask layer includes silicon nitride, silicon carbon nitride or a combination thereof.

According to an embodiment of the present invention, the gate dielectric layer includes silicon oxide, a high-k material, or a combination thereof.

According to an embodiment of the present invention, the method further includes forming a contact etching stop layer between the spacer and the first dielectric layer.

The present invention further provides a method of forming a semiconductor device. Provided is a substrate having a metal gate formed thereon, a spacer on sidewall of the metal gate and a first dielectric layer surrounding the spacer. A hard mask layer is formed to cover top surfaces of the metal gate and the spacer. A second dielectric layer is formed to cover the hard mask layer and the first dielectric layer. A portion of the second dielectric layer and a portion of the first dielectric layer are removed to form a contact opening. A contact plug is formed in the contact opening.

According to an embodiment of the present invention, the hard mask layer and the spacer have different removing rates.

According to an embodiment of the present invention, the hard mask layer includes silicon nitride, silicon carbon nitride or a combination thereof.

According to an embodiment of the present invention, the step of forming the metal gate includes: forming at least one work function layer; and forming a low-resistivity metal layer.

According to an embodiment of the present invention, the method further includes forming a gate dielectric layer before the metal gate is formed.

According to an embodiment of the present invention, the method further includes forming a contact etching stop layer between the spacer and the first dielectric layer.

According to an embodiment of the present invention, the method further includes forming epitaxial layers beside the dummy gate after the spacer is formed, wherein the contact is electrically connected to one of the epitaxial layers.

In view of the above, a hard mask layer is formed to replace a portion of the damaged spacer after the metal gate is formed, so as to provide an improved etching selectivity during the contact plug forming process. Therefore, a short current does not occur between the metal gate and the adjacent contact plug and the device performance can be accordingly improved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1H schematically illustrates cross-sectional views of a method of forming a semiconductor device according to a first embodiment of the present invention.

FIG. 2 schematically illustrates cross-sectional views of a semiconductor device according to a second embodiment of the present invention.

FIG. 3 schematically illustrates cross-sectional views of a semiconductor device according to a third embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

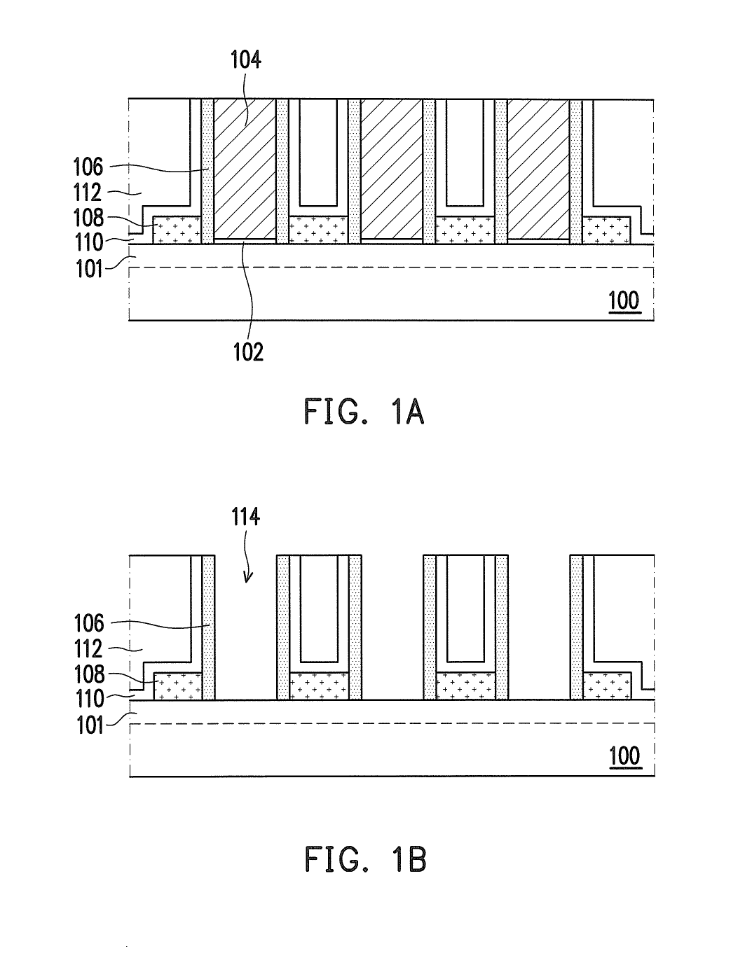

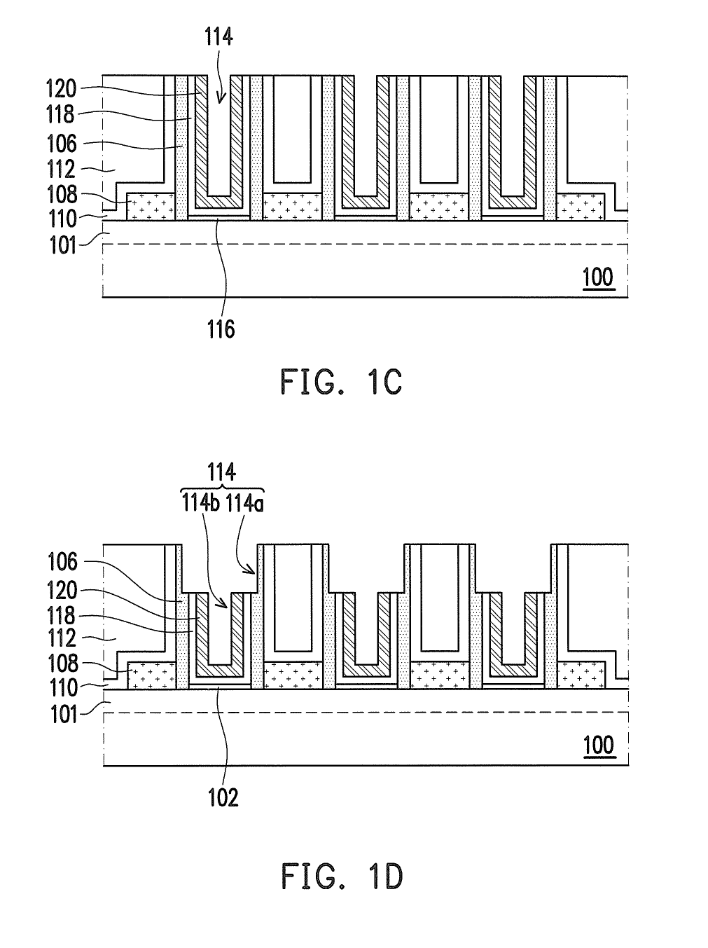

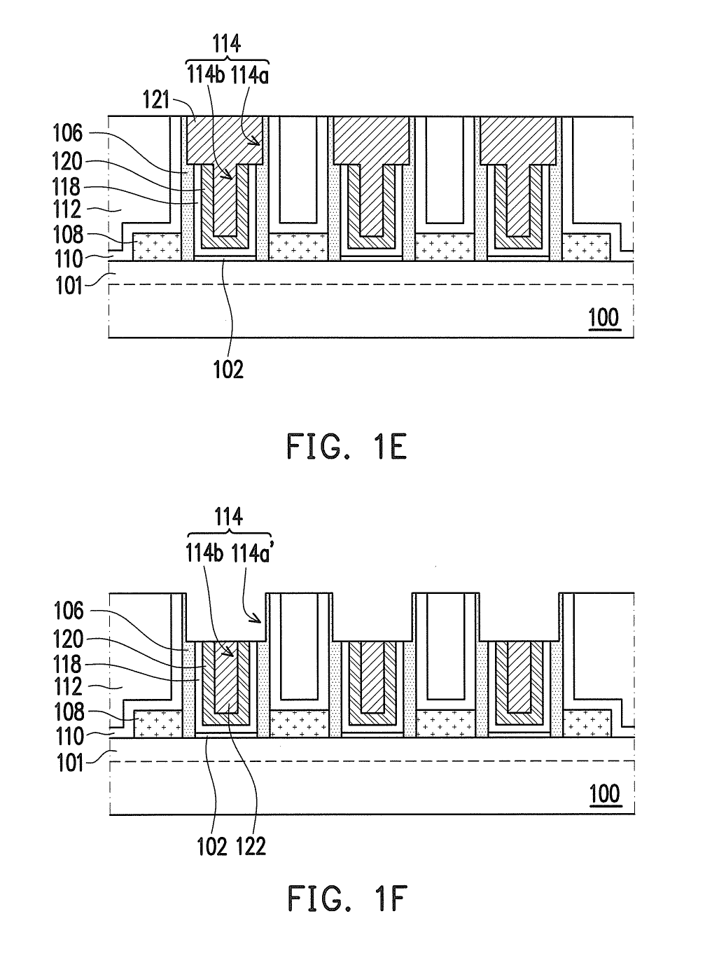

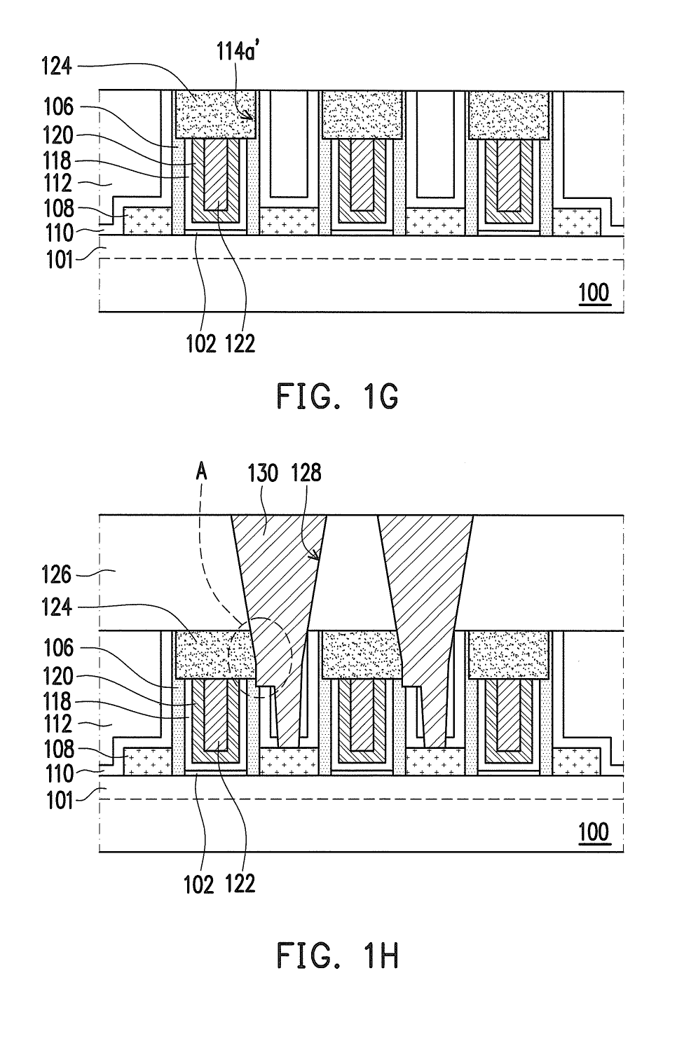

FIG. 1A to FIG. 1H schematically illustrates cross-sectional views of a method of forming a semiconductor device according to a first embodiment of the present invention.

Referring to FIG. 1A, a semiconductor substrate 100 having multiple dummy gates 104 is provided. The semiconductor substrate can be a silicon-containing substrate 100 with multiple fins 101 extending in a first direction. An insulating layer (not shown) is formed to fill the lower portions of gaps between the fins 101. The insulating layer includes silicon oxide.

The dummy gates 104 cross the fins 101 and extend in a second direction different from the first direction. In an embodiment, the second direction is perpendicular to the first direction. The dummy gates 104 include amorphous silicon, polysilicon or a combination thereof. In an embodiment, an interfacial layer 102 is optionally formed between each dummy gate 104 and the substrate 100. The interfacial layer 102 includes silicon oxide.

Besides, the substrate 100 further has spacers 106 and epitaxial layers 108 formed thereon. Specifically, spacers 106 are formed respectively on the sidewalls of the dummy gates 104. The spacers 106 include silicon oxide, silicon nitride, silicon oxynitride or a combination thereof. After the formation of the spacers 106, the epitaxial layers 108 are formed on the fins 101 between the dummy gates 104, and two adjacent dummy gates 104 share one epitaxial layer 108. Besides, the epitaxial layers 108 cover the lower sidewalls of the spacers 106. The epitaxial layers 108 serve as source/drain regions of the device and may include doped regions therein. In an embodiment, the epitaxial layers 108 can be combination of P-type doped regions and SiGe layers, but the present invention is not limited thereto. In another embodiment, the epitaxial layers 108 can be combination of N-type doped regions and SiC or SiP layers. The SiGe or SiC layers are formed with a selective epitaxy growth (SEG) process. The P-type or N-type doped regions are formed with an ion implantation process.

Continue referring to FIG. 1A, the substrate 100 further has a contact etch stop layer (CESL) 110 and a dielectric layer 112 formed thereon. The CESL 110 and the dielectric layer 112 fill up the gaps between the dummy gates 104 but expose the tops of the dummy gates 104. Specifically, the CESL 110 is formed to cover the top surfaces of the epitaxial layers 108 and the spacers 106 exposed by the epitaxial layers 108, and the dielectric layer 112 is formed on the CESL 110 to fill up the gaps between the dummy gates 104. In other words, the CESL 110 is formed between each spacer 106 and the dielectric layer 112, and the dielectric layer 112 is formed to surround the spacers 106. The CESL 110 includes silicon nitride. The dielectric layer 112 includes silicon oxide, a low-k material, a suitable insulating material or a combination thereof.

Referring to FIG. 1B, the dummy gates 104 are removed to form gate trenches 114. The removing step includes performing an etching process. Herein, each interfacial layer 102 can be regarded as a sacrificial layer since it is removed during the step of removing the dummy gates 104.

Referring to FIG. 1C, another interfacial layer 116 and a gate dielectric layer 118 and at least one work function layer 120 are formed in each gate trench 114. Specifically, each interfacial layer 116 can be a silicon oxide layer formed on the bottom surface of the corresponding gate trench 114. The interfacial layers 116 can be formed by a furnace process. Each gate dielectric layers 118 includes silicon oxide, a high-k material layer or a combination thereof. In an embodiment, each gate dielectric layer 118 can be a high-k material layer formed on the bottom surface and the sidewall of the corresponding gate trench 114. The high-k material layer can be metal oxide, such as rare earth metal oxide. The high-k material can be selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate, (SrBi₂Ta₂O₉, SBT), lead zirconate titanate (PbZrₓTi₁₋ₓO₃, PZT), and barium strontium titanate (BaₓSr₁₋ₓTiO₃, BST), wherein x is between 0 and 1. The gate dielectric layers 118 can be formed by a deposition process, such as an ALD process, a CVD process, a PVD process or a sputter deposition process.

The work function layers 120 are respectively formed on the gate dielectric layers 118. For a P-type device, the work function layer 120 can be a double-layer structure, wherein the lower work function layer includes titanium nitride (TiN), titanium carbide (TiC), tantalum nitride (TaN), tantalum carbide (TaC), tungsten carbide (WC) or aluminum titanium nitride (TiAlN), and the upper work function layer includes titanium aluminide (TiAl), zirconium aluminide (ZrAl), tungsten aluminide (WAl), tantalum aluminide (TaAl) or hafnium aluminide (HfAl). For an N-type device, the work function layer 120 can be a single-layer structure including titanium aluminide (TiAl), zirconium aluminide (ZrAl), tungsten aluminide (WAl), tantalum aluminide (TaAl) or hafnium aluminide (HfAl). The work function layer 120 can be formed by a deposition process, such as an ALD process, a CVD process, a PVD process or a sputter deposition process.

Referring to FIG. 1D, each work function layer 120 and the corresponding gate dielectric layer 118 are pulled down, and a portion of the corresponding spacer 106 is laterally removed at the same time to widen or broaden the top portion of the corresponding gate trench 114. Therefore, each gate trench 114 is formed with a bottom portion 114b and a top portion 114a wider than the bottom portion 114b. The pull-down step and the widening step are performed by an etching back process.

Referring to FIG. 1E and FIG. 1F, a low-resistivity metal layer 122 is formed in the bottom portion 114b of each gate trench 114. The method of forming the low-resistivity metal layer 122 includes forming a low-resistivity metal material layer 121 on the substrate 100 filling the gate trenches 114. The low-resistivity metal material layer 121 includes W, Al or Cu and the forming method thereof includes performing a deposition process such as PVD or CVD. Thereafter, referring to FIG. 1E, the low-resistivity metal material layer 121 outside of the gate trenches 114 are removed with a CMP process.

Afterwards, referring to FIG. 1F, the low-resistivity metal material layer 121 in the top portion of each gate trench 114 is removed with an etching back process, and thus, each low-resistivity metal layer 122 is formed in the bottom portion 114b of the corresponding gate trench 114. During the etching back process, another portion of each spacer 106 is laterally removed, so as to further widen the top portion of each gate trench 114. Therefore, the top portion 114a′ wider than the top portion 114a is formed.

In an embodiment, after the removing step of FIG. 1F, there is still a small amount of each spacer 106 remaining adjacent to the top portion of the corresponding gate trench 114, as shown in FIG. 1F. However, the present invention is not limited thereto. In another embodiment (not shown), each spacer 106 adjacent to the top portion of the corresponding gate trench 114 is completely removed, and thus, the subsequently formed hard mask layer 124 contacts the CESL 110.

Referring to FIG. 1G, a hard mask layer 124 is formed in the widened top portion 114a′ of each gate trench 114. The method of forming the hard mask layers 118 includes forming a hard mask material layer (not shown) on the substrate 100 filling the top portions 114a′ of the gate trenches 114. The hard mask layer 124 and the dielectric layer 112 can include different materials. In this embodiment, the hard mask layer 124 and the spacer 106 include the same material (e.g. SiN). However, the present invention is not limited thereto. In another embodiment, the hard mask layer 124 and the spacer 106 can include different materials. The hard mask material layer includes silicon nitride, silicon carbon nitride or a combination thereof, and the forming method thereof includes performing a deposition process such as PVD or CVD. Thereafter, the hard mask material layer outside of the gate trenches 114 are removed with a CMP process.

Referring to FIG. 1H, a dielectric layer 126 is formed to cover the hard mask layers 118 and the dielectric layer 112. The dielectric layer 126 includes silicon oxide, a low-k material, a suitable insulating material or a combination thereof. Besides, the material of the dielectric layer 126 can be the same as or different from that of the dielectric layer 112. The dielectric layer 126 and the spacer 106 can include different materials. The dielectric layer 126 can be formed with a suitable deposition process such as PVD or CVD.

Thereafter, a portion of the dielectric layer 126 and a portion of the dielectric layer 112 are removed to form multiple contact openings 128 therein. The removing step includes a photolithography step followed by an etching step. The removing step simultaneously removes a portion of the CESL 110, so that the contact openings 128 expose a portion of the epitaxial layers 108 between metal gates including the work function layer 120 and the low-resistivity metal layer 122. Herein, the step of forming the contact openings 128 is also called a self-aligned contact (SAC) etching process. Afterwards, contact plugs 130 are respectively formed in the contact openings 128. The contact plugs 30 include metal such as tungsten, Al, Cu, Ti or a combination thereof. In other words, the contact plugs 30 are electrically connected to the corresponding epitaxial layers 110.

In view of the above, provided is a substrate 100 having a metal gate (including the work function layer 120 and the low-resistivity metal layer 122) formed thereon, a spacer 106 on sidewall of the metal gate and a dielectric layer 112 surrounding the spacer 106, as shown in FIG. 1F. Thereafter, a hard mask layer 124 is formed to cover top surfaces of the metal gate and the spacer 106, as shown in FIG. 1G. Afterwards, as shown in FIG. 1H, a dielectric layer 126 is formed to cover the hard mask layer 124 and the dielectric layer 112. A portion of the dielectric layer 120 and a portion of the dielectric layer 112 are removed to form contact openings 128. Contact plugs 130 are formed in the contact openings 128.

It is known that the spacer beside the metal gate is subjected to multiple implantation steps, cleaning steps and annealing steps and is therefore damaged, so that the hardness of the damaged spacer is decreased without providing enough etching selectivity with respect to the dielectric layer(s), and thus, a short occurs between the metal gate and the adjacent contact plug. However, such short current is not observed in the present invention.

Specifically, for a conventional contact plug forming process, once a misalignment occurs during the photolithography step for defining the contact hole, the succeeding etching step may etch away an upper portion of the CESL and an upper portion of the damaged spacer beside the metal gate. Alternatively, even though a misalignment does not occur during the photolithography step for defining the contact hole, the succeeding etching step may over-etch and therefore remove the upper portions of the CESL and the damaged spacer beside the metal gate. In both cases, the subsequently formed contact plug may directly connect the metal gate to create a short.

However, such short current is not observed during the contact plug forming process of the invention. Specifically, at least a portion of each spacer 106 adjacent to the top portion of the corresponding gate trench 114 is removed (as shown in FIG. 1D and FIG. 1F); in other words, each spacer 106 in FIG. 1F is provided with an upper thickness thereof smaller than a lower thickness thereof. Thereafter, the hard mask layer 124 is formed to fill the removing portion of each spacer 106. Herein, the hard mask layer 124 and the spacer 106 are provided with different removing rates or etching selectivities. Specifically, since the hard mask layer 124 has a hardness greater than that of the damaged spacer 106, the hard mask layer 124 can provide enough etching selectivity with respect to the dielectric layers 112/126, and therefore avoid a short from occurring between the metal gate (including the work function layer 120 and the low-resistivity metal layer 122) and the adjacent contact plug 130. More specifically, as shown in the FIG. 1H, the hard mask layer 124 provides a strong resistance to the etching step during the contact plug forming process, as shown in the area A.

The first embodiment in which the described method is applied to form a Fin Field-Effect Transistor (FinFET) device is provided for illustration purposes, and is not construed as limiting the present invention. It is appreciated by people having ordinary skill in the art that the described method can be applied to form a planar device including a metal gate or a polysilicon gate.

### Second Embodiment

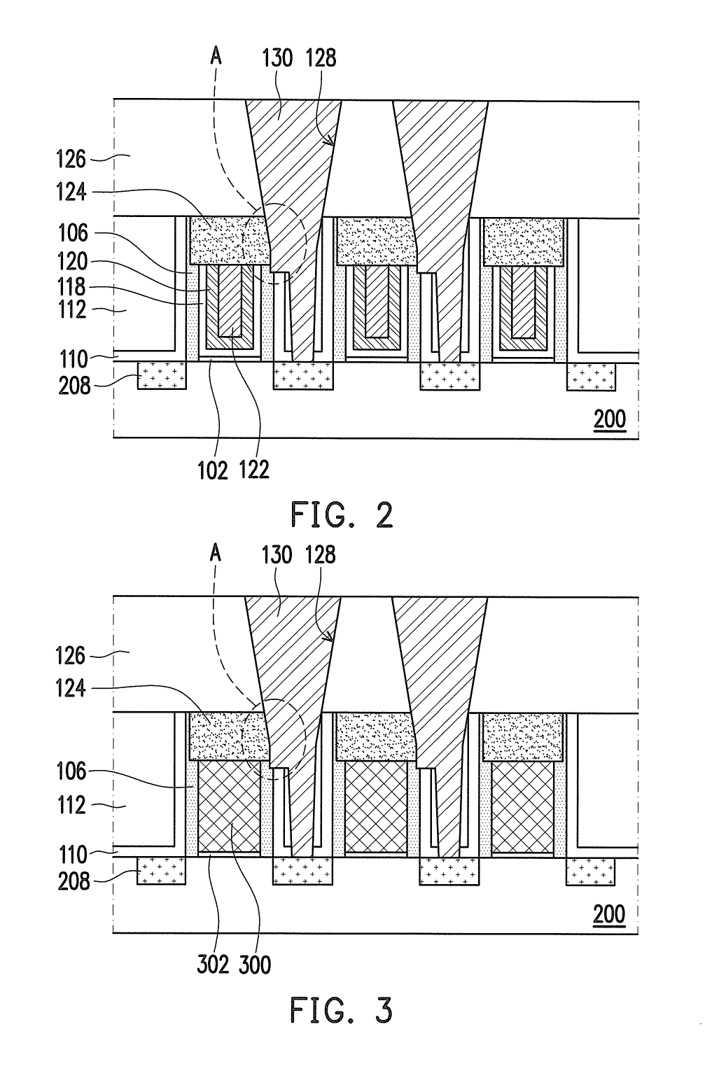

FIG. 2 schematically illustrates cross-sectional views of a semiconductor device according to a second embodiment of the present invention.

The difference between the second and first embodiments lies in that the substrate of the second embodiment is a bulk substrate 200 while the substrate of the first embodiment is a substrate 100 with fins 101; and the epitaxial layers 208 of the second embodiment are formed in the substrate 100 beside the metal gate while the epitaxial layers 108 of the first embodiment are formed on the fins 101 beside the metal gate. The process steps similar to those as described in FIGS. 1A to 1H are implemented, so as to obtain a planar device including a metal gate including the work function layer 120 and the low-resistivity metal layer 122, as shown in FIG. 2. It is noted that, the hard mask layer 124 covers top surfaces of the metal gate and the gate dielectric layer 118 and the damaged spacer 106, so as to provide a strong resistance to the etching step during the contact plug forming process, as shown in the area A of FIG. 2.

### Third Embodiment

FIG. 3 schematically illustrates cross-sectional views of a semiconductor device according to a third embodiment of the present invention.

The difference between the third and second embodiments lies in that the gate of the third embodiment is a polysilicon gate 300 while the gate of the second embodiment is a metal gate including the work function layer 120 and the low-resistivity metal layer 122; a gate dielectric layer 302 of the third embodiment is formed on the bottom surface of the gate trench while the gate dielectric layer 118 of the second embodiment is formed on the bottom surface and the sidewall of the gate trench; and the interfacial layer 102 of the second embodiment is omitted in the third embodiment. The process steps similar to those as described in FIGS. 1A to 1H are implemented, so as to obtain a planar device including a polysilicon gate 300, as shown in FIG. 3. It is noted that, the hard mask layer 124 covers top surfaces of the polysilicon gate 300 and the damaged spacer 106, so as to provide a strong resistance to the etching step during the contact plug forming process, as shown in the area A of FIG. 3.

In summary, in the method of the present invention, a hard mask layer is formed to replace a portion of the damaged spacer after the metal gate is formed, and therefore provide enough etching selectivity with respect to the dielectric layer(s). With such manner, the hard mask layer provides a strong resistance to the etching step during the contact plug forming process. In other words, the conventional short current between the metal gate and the adjacent contact plug is not observed, so that the device performance can be accordingly improved.

With such method, even though a rework of the second photolithography step occurs, the film stack of the invention can provide enough protection for the underlying layers. Specifically, in the present invention, all the components (including SiGe source/drains) are protected by at least a portion of the tri-layer hard mask after the first etching step, and therefore free of any possible damage during the rework.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of fabricating a semiconductor device, comprising:
providing a substrate having a dummy gate formed thereon, a spacer on a sidewall of the dummy gate and a first dielectric layer surrounding the spacer,
removing the dummy gate to form a gate trench;
forming a gate dielectric layer and at least one work function layer in the gate trench;
pulling down the work function layer and the gate dielectric layer, and laterally removing a portion of the spacer at the same time to widen a top portion of the gate trench;
forming a low-resistivity metal layer in a bottom portion of the gate trench; and
forming a hard mask layer in the widened top portion of the gate trench.

2. The method of fabricating the semiconductor device according to claim 1, further comprising:
forming a second dielectric layer covering the hard mask layer and the first dielectric layer;
removing a portion of the second dielectric layer and a portion of the first dielectric layer to form a contact opening; and
forming a contact plug in the contact opening.

3. The method of fabricating the semiconductor device according to claim 2, wherein the hard mask layer and the spacer have different removing rates.

4. The method of fabricating the semiconductor device according to claim 2, wherein the substrate is a substrate with fins extending in a first direction, and the dummy gate crosses the fins and extend in a second direction different from the first direction.

5. The method of fabricating the semiconductor device according to claim 4, further comprising forming epitaxial layers on the fins beside the dummy gate after the spacer is formed, wherein the contact plug is electrically connected to one of the epitaxial layers.

6. The method of fabricating the semiconductor device according to claim 2, wherein the substrate is a bulk substrate.

7. The method of fabricating the semiconductor device according to claim 6, further comprising forming epitaxial layers in the substrate beside the dummy gate after the spacer is formed, wherein the contact plug is electrically connected to one of the epitaxial layers.

8. The method of fabricating the semiconductor device according to claim 1, wherein the step of forming the low-resistivity metal layer comprises:
forming a low-resistivity metal material layer on the substrate filling the gate trench;
removing the low-resistivity metal material layer outside of the gate trench; and
removing the low-resistivity metal material layer in the top portion of the gate trench.

9. The method of fabricating the semiconductor device according to claim 8, further comprising laterally removing another portion of the spacer during the step of removing the low-resistivity metal material layer in the top portion of the gate trench, so as to further widen the top portion of the gate trench.

10. The method of fabricating the semiconductor device according to claim 8, wherein the step of removing the low-resistivity metal material layer outside of the gate trench comprises performing a CMP process.

11. The method of fabricating the semiconductor device according to claim 1, wherein the hard mask layer comprises silicon nitride, silicon carbon nitride or a combination thereof.

12. The method of fabricating the semiconductor device according to claim 1, wherein the gate dielectric layer comprises silicon oxide, a high-k material, or a combination thereof.

13. The method of fabricating the semiconductor device according to claim 1, further comprising forming a contact etching stop layer between the spacer and the first dielectric layer.

14. A method of fabricating a semiconductor device, comprising:
providing a substrate having a metal gate formed thereon, a spacer on sidewall of the metal gate and a first dielectric layer surrounding the spacer;
forming a hard mask layer covering top surfaces of the metal gate and the spacer;
forming a second dielectric layer covering the hard mask layer and the first dielectric layer;
removing a portion of the second dielectric layer and a portion of the first dielectric layer to form a contact opening; and
forming a contact plug in the contact opening.

15. The method of fabricating the semiconductor device according to claim 14, wherein the hard mask layer and the spacer have different removing rates.

16. The method of fabricating the semiconductor device according to claim 14, wherein the hard mask layer comprises silicon nitride, silicon carbon nitride or a combination thereof.

17. The method of fabricating the semiconductor device according to claim 14, wherein the step of forming the metal gate comprises:
forming at least one work function layer; and
forming a low-resistivity metal layer.

18. The method of fabricating the semiconductor device according to claim 14, further comprising forming a gate dielectric layer before the metal gate is formed.

19. The method of fabricating the semiconductor device according to claim 14, further comprising forming a contact etching stop layer between the spacer and the first dielectric layer.

20. The method of fabricating the semiconductor device according to claim 14, further comprising forming epitaxial layers beside the dummy gate after the spacer is formed, wherein the contact is electrically connected to one of the epitaxial layers.
